(19) United States
(12) Patent Application Publication
(10) Pub. No.: US 2012/0194571 A1
(43) Pub. Date: Aug. 2, 2012

(54) IMAGE DRIVER AND DISPLAY HAVING MULTIPLE GAMMA GENERATOR

(76) Inventors: Chien-Ru Chen, Ligang Township (TW); Ying-Lieh Chen, Tainan City (TW)

(21) Appl. No.: 13/363,736

(22) Filed: Feb. 1, 2012

(30) Foreign Application Priority Data
Feb. 1, 2011 (TW) 100103845

(51) Int. Cl. G09G 5/10; H03L 5/00

(52) U.S. Cl. 345/690; 327/306

(57) ABSTRACT

An image driver includes an adjustment signal module, a multiplexer, and a conversion module. The adjustment module generates at least a first adjustment signal and a second adjustment signal. The multiplexer is connected to the adjustment signal module and selectively outputs one of the adjustment signals. The conversion module includes a plurality of conversion units, wherein each of the conversion units receives the selected adjustment signal and generates a driving signal based on the adjustment signal received.

### BACKGROUND OF THE INVENTION

1. Field of the Invention

This invention relates to an image driver and a display having the same, specifically to an image driver having a plurality of gamma generator and a display having the same.

2. Description of the Prior Art

Various displays on the market such as cathode ray tube (CRT) displays, liquid crystal displays (LCD), organic light emitting diode (OLED) displays are non-linear devices whose response exhibits a power law distribution with respect to the voltages applied. In other words, the luminance generated by the display is not directly proportional to the voltages applied. Furthermore, the sensitivity of human visual system toward variation in luminance is different in dark environment and in bright environment. Normally, human visual system is more sensitive to light in dark environment. Therefore, the luminance variation generated by the display creates a non-uniform visual effect on luminance variation sensed by the human visual system.

In order to solve the problem mentioned above, the conventional methodology generates a plurality of gamma signals in the driving integrated circuit of the display, wherein the gamma signals are incorporated with the existing driving signals to become new signals for driving the display panel. The luminance variation generated by the display panel driven by new signals can be used to generate luminance that is more linear with respect to the human visual system. Thus, the compensation for non-linearity mentioned above prevents the non-linearity of luminance sensed by the human visual system.

The conventional driving integrated circuit use only one gamma signal for adjusting the luminance variation for each display panel. However, different portions of the display panel may need different gamma signals for adjustment. Furthermore, different types of displays have different curves of luminance variation and therefore the same driving integrated circuit may not be suitable for every type of display panels. Thus, the driving integrated circuit may require a plurality of gamma generators to accommodate the characteristics of different displays and different image display requirements.

However, using a plurality of gamma generators inevitably increases the overall thickness of the driving integrated circuit and thus reduces the space left for other components. Thus, how to maintain the overall thickness and size of the driving integrated circuit while using a plurality of gamma generators is indeed an important issue for the display panel design.

### SUMMARY OF THE INVENTION

It is an objective of the present invention to provide a display and an image driver thereof that can select a suitable adjustment signal based on the variation of luminance of the display relative to the human visual system.

It is another objective of the present invention to provide a display and an image driver thereof for selecting suitable adjustment signals based on the requirements of different pixel units and transmitting the selected adjustment signals to the corresponding pixel units.

The image driver of the present invention includes an adjustment signal module, a multiplexer, and a conversion module. The adjustment signal module preferably includes a first adjustment module and a second adjustment module for generating a digital first adjustment signal and a digital second adjustment signal respectively. The multiplexer receives the adjustment signals and transmit one of the adjustment signals to the conversion module, so that the digital-to-analog conversion module can convert the digital adjustment signal received to an analog adjustment signal. The digital-to-analog conversion module then combines the adjustment signal with the driving signal and outputs the resultant signal to the pixel units of a display panel. In this way, the combination of the adjustment signal and the driving signal can be used to maintain the variation of the luminance of the display relative to the human visual system.

The image driver of the present invention, in one embodiment, uses only one of the first adjustment signal and the second adjustment signal as reference to adjust the variation of luminance, but is not limited thereto. In different embodiments, the multiplexer can include a switching unit to switch the adjustment signal outputted by the multiplexer.

The above is a detailed description of the particular embodiment of the invention which is not intended to limit the invention to the embodiment described. It is recognized that modifications within the scope of the invention will occur to a person skilled in the art. Such modifications and equivalents of the invention are intended for inclusion within the scope of this invention.

### BRIEF DESCRIPTION OF THE DRAWINGS

FIG. 1 is a block diagram of the display of the present invention;

FIG. 2 is a block diagram of the image driver of the present invention;

FIG. 3 is a block diagram illustrating another embodiment of the image driver of the present invention;

FIG. 4 is a block diagram illustrating a variation of the image driver illustrated in FIG. 3;

FIG. 5A and FIG. 5B illustrate another variation of the image driver illustrated in FIG. 3; and

FIG. 6A and FIG. 6B illustrate a variation of the image driver illustrated in FIG. 5A and FIG. 5B.

### DETAILED DESCRIPTION

Embodiments of the present invention relate to an image driver, specifically an image driver having a plurality of gamma generators. The image driver of the present invention is preferably used to drive the pixel units of the liquid crystal display, but is not limited thereto; in different embodiments, the structure of the image driver of the present invention can be used in other types of displays.

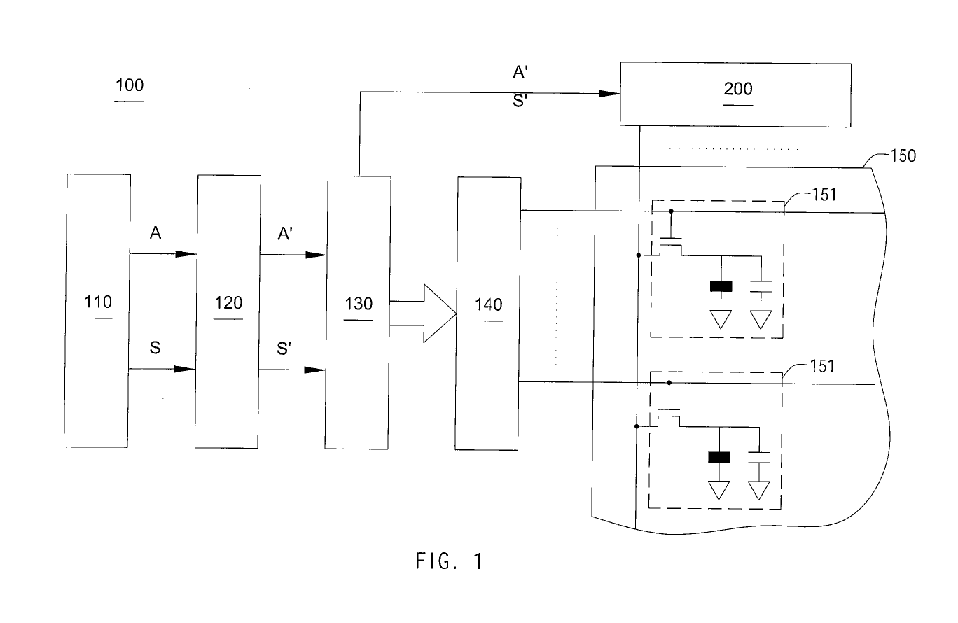

FIG. 1 is a block diagram of the flat display 100 of the present invention. The flat display 100 of the present embodiment includes an image controller 110, an analog-to-digital converter 120, a timing controller 130, a gate driving module 140, a display panel 150, and an image driver 200. As FIG. 1 shows, the image controller 110 transmits analog signals, such as analog color field signals A and analog synchronization signals S, to the analog-to-digital converter 120 to be converted to digital signals, such as digital color field signals A′ and digital timing signals S′. The analog synchronization signals S includes convention horizontal synchronization signals (HSYNC) and vertical synchronization signals (VSYNC) used to instruct the timing controller 130 about the timing sequence to drive the display panel 150 and are not elaborated here. The analog-to-digital converter 120 uses the signals mentioned above to generate digital color filed signals A′ and synchronizations signals that is used to indicate the timing sequence of driving the display panel 150, wherein those signals are then transmitted to the timing controller 130.

In the embodiment illustrated in FIG. 1, the display panel 150 is a liquid crystal display panel including a plurality of pixel units 151, wherein each pixel unit 151 includes a thin-film transistor, a storage capacitor, and a liquid crystal capacitor. The timing controller 130 controls the gate driving module 140 to send voltages to the gates of the thin-film transistors of different pixel units 151, based on the digital timing signal S′. In this way, current can pass through the source and the gate of the thin-film transistor as well as the storage capacitor and the liquid crystal capacitor. In other words, the gate of the thin-film transistor is essentially a switch used to control the current flowing through of the thin-film transistor.

In the embodiment illustrated in FIG. 1, after voltages are transmitted to the gates of the thin-film transistors of the pixel units 151, the timing controller 130 then controls the image driver 200 to output voltages to the sources of the thin-film transistors. By doing so, the image driver 200 charges the storage capacitor and the liquid crystal capacitor through the source and the gate of the thin-film transistor. In this way, the timing controller 130 illustrated in FIG. 1 can use the gate driving module 140 and the image driver 200 to control the twist of the liquid crystal molecules within the pixel unit 151 as well as the luminance generated by the display panel 150.

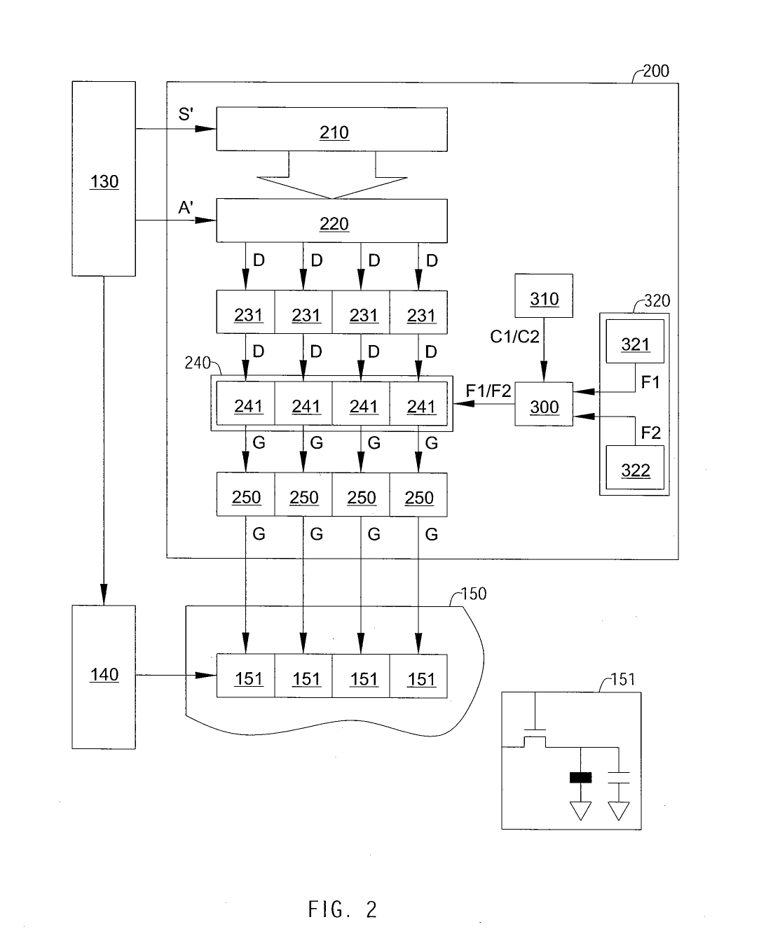

FIG. 2 is a block diagram of the image driver 200 of the present invention. As FIG. 2 shows, the image driver 200 includes a timing controller module 210, an image signal module 220, data latches 231, a digital-to-analog conversion module 240, a plurality of buffer amplifiers 250, a multiplexer 300, a selection signal module 310, and an adjustment signal module 320.

In the present embodiment, the timing controller module 210 and the image signal module 220 are connected to the timing controller 130 illustrated in FIG. 1 to receive the digital timings signal S′ and the digital color field signal A′ from the timing controller 130 respectively. The image signal module 220 transmits a plurality of digital driving signals D to the data latches 231 to be stored temporarily, based on the timing sequence indicated by the digital timing signal S′ and the digital color field signal A′ received. Each of the digital driving signals D mentioned above corresponds to one of the pixel units 151 in the display panel 150. Furthermore, the digital-to-analog conversion module 240 will generate a plurality of analog driving signals based on the digital driving signals D received, wherein the analog driving signals are transmitted to the sources of the thin-film transistors of the pixel units 151, through the buffer amplifiers 250.

It needs to be explained here that the sensibility of human visual system toward the variation in luminance is different in dark environment and in bright environment, wherein the human visual system are more sensitive to light and its variation in dark environment. Therefore, the luminance variation generated by the display 100 creates a non-uniform visual effect on the luminance variation sensed by the human visual system. In other words, for users, the luminance generated by the display 100 is not directly proportional to the voltages (analog driving signals) that are inputted to the display panel 150 for driving the liquid crystal molecules.

In order to solve the problem mentioned above, the image driver 200 of the present invention uses the adjustment signal module 320 to generate a plurality of analog adjustment signals F1, F2 (gamma signal) to be incorporated into the digital driving signals D. The incorporated adjustment signals F1, F2 and digital driving signals D are then used to drive the liquid crystal molecules in the pixel units 151 so that the luminance variation of the display 100 can be visually average to the human visual system.

In the embodiment illustrated in FIG. 2, the multiplexer 300 transmits the adjustment signals F1, F2 to the digital-to-analog conversion module 240. Furthermore, the digital-to-analog conversion module 240 incorporates the adjustment signals F1, F2 with the digital driving signal D and then generates a gamma driving signal G that is then sent to the corresponding pixel unit 151. In this way, the luminance variation of the display 150, compared with the conventional display without utilizing the adjustment signals F1, F2, appears visually average to the human visual system.

In the embodiment illustrated in FIG. 2, the adjustment signal module 320 includes a first adjustment module 321 and a second adjustment module 322 for generating an analog first adjustment signal F1 (gamma signal) and an analog second adjustment signal F2 (gamma signal) respectively. Moreover, the digital-to-analog conversion module 240 includes a plurality of conversion units 241. In the present embodiment, the multiplexer 300 will output the first adjustment signal F1 to the digital-to-analog conversion module 240 after receiving the first selection signal C1. On the other hand, the multiplexer 300 will output the second adjustment signal F2 to the digital-to-analog conversion module 240 after receiving the second selection signal C2.

As FIG. 2 shows, the multiplexer 300 is connected to the first adjustment module 321 and the second adjustment module 322 to receive the first adjustment signal F1 and the second adjustment signal F2, respectively. In addition, the selection signal module 310 will selectively output a first selection signal C1 or a second selection signal C2 to the multiplexer 300, wherein the first selection signal C1 and the second selection signal C2 correspond to the first adjustment signal F1 and the second adjustment signal F2 respectively.

Furthermore, in the embodiment illustrated in FIG. 2, the conversion units 241 of the digital-to-analog conversion module 240 receive the digital driving signals D from the data latches 231 for generating the gamma driving signals G, but are not limited thereto. In different embodiments, the voltage of the digital driving signal D generated by the data latch 231 may be insufficient to drive the pixel unit 151. In this case, the digital driving signals D can first be boosted by level shifters and then transmitted to the conversion units 241 of the digital-to-analog conversion module 240.

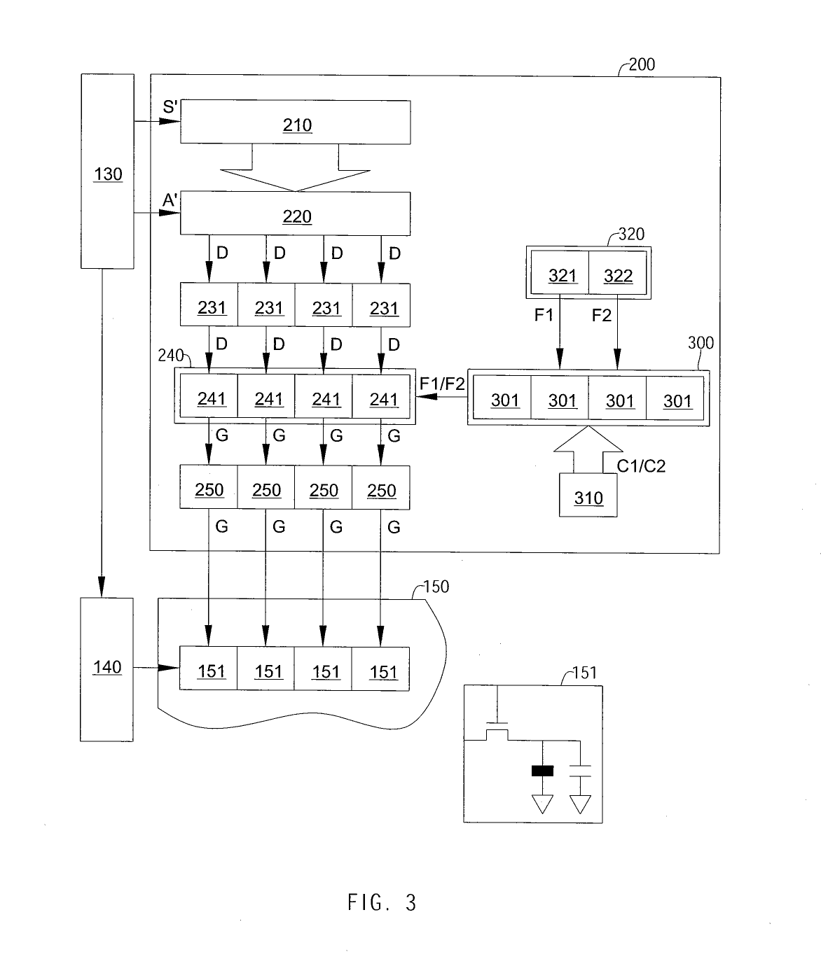

FIG. 3 is a variation embodiment of the image driver 200 of the present invention. In the present embodiment, the multiplexer 300 includes a plurality of multiplexer units 301, wherein each of the multiplexer units 301 corresponds to one of the conversion units 241. Furthermore, each multiplexer unit 301 receives the first adjustment signal F1 and the second adjustment signal F2 from the adjustment signal module 320 and outputs one of the adjustment signals F1, F2 to the corresponding conversion unit 241, based on the command from the selection signal module 310.

In the present embodiment, each of the multiplexer units 301 receives one of the first selection signal C1 and the second selection signal C2 from the selection signal module 310 and outputs the corresponding adjustment signal F1/F2 to the conversion unit 241.

Furthermore, in the embodiments illustrated in FIG. 2 and FIG. 3, the selection signal module 310 is configured to output one of the first selection signal C1 and the second selection signal C2 to the multiplexer 300 or multiplexer units 301. Thus, the multiplexer 300 or multiplexer units 301 illustrated in FIG. 2 or FIG. 3 will output only one of the first adjustment signal F1 and the second adjustment signal F2, but the present invention is not limited thereto.

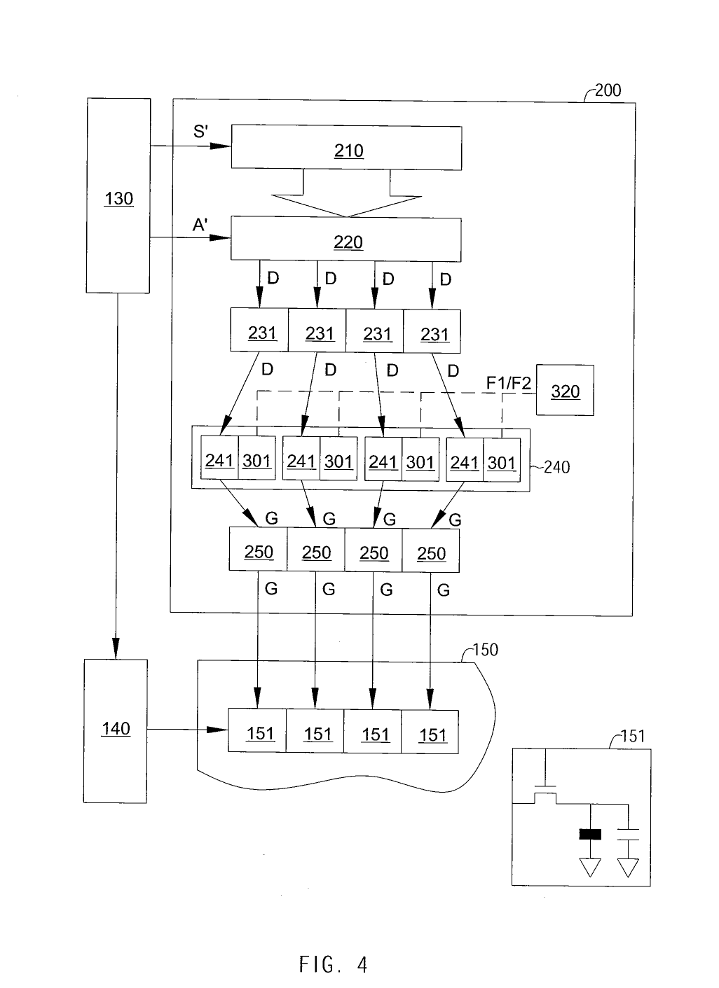

FIG. 4 is a variation of the image driver 200 illustrated in FIG. 3. As FIG. 4 shows, each of the multiplexer units 301 included in the image driver 200 is disposed in the digital-to-analog conversion module 240 and connected to one of the conversion units 241. In the present embodiment, the adjustment signal module 320 outputs both the first adjustment signal F1 and the second adjustment signal F2 to each multiplexer unit 301. The multiplexer unit 301 then outputs one of the first adjustment signal F1 and the second adjustment signal F2 to the conversion unit 241 based on the selection signal generated by the selection signal module (not illustrated). The conversion unit 241 accepts the digital driving signal D from the data latch 231 and then outputs the gamma driving signal G to the corresponding buffer amplifier 250 based on the adjustment signal received from the adjustment signal module 320. Afterward, the buffer amplifier 250 amplifies the voltage of the gamma driving signal G and then transmits the gamma driving signal G to the corresponding pixel units 151. Furthermore, other than the feature that the multiplexer units 301 are integrated into the digital-to-analog conversion module 240, the image drivers 200 illustrated in FIG. 3 and FIG. 4 are substantially the same in respect to functionality and overall structure and therefore are not elaborated here.

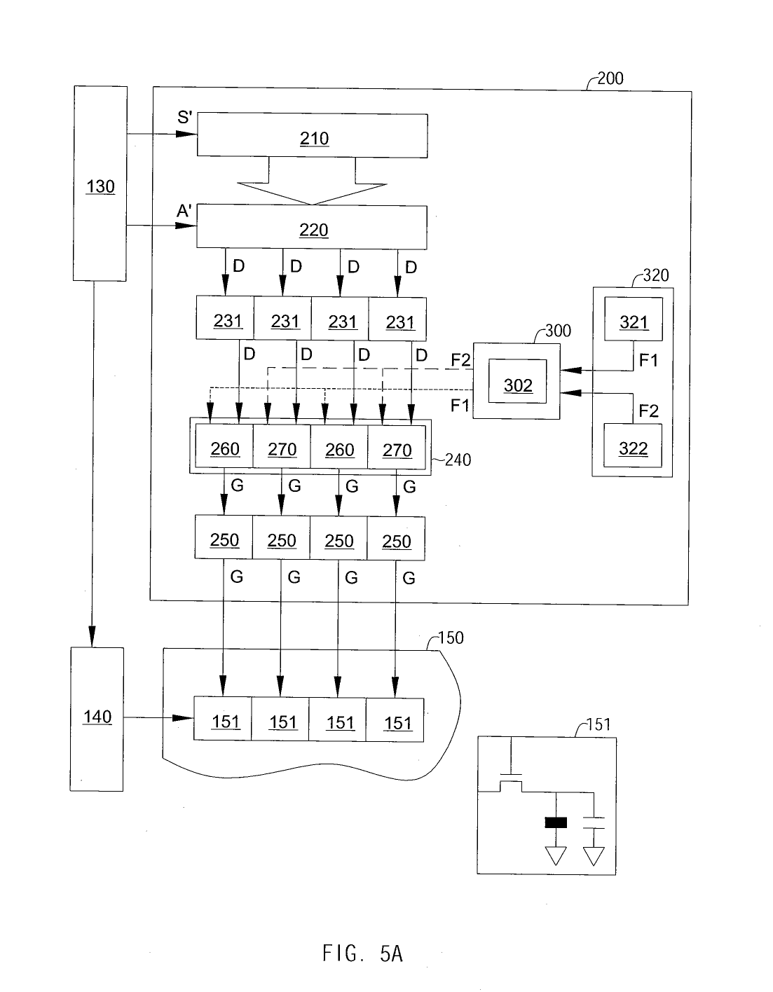

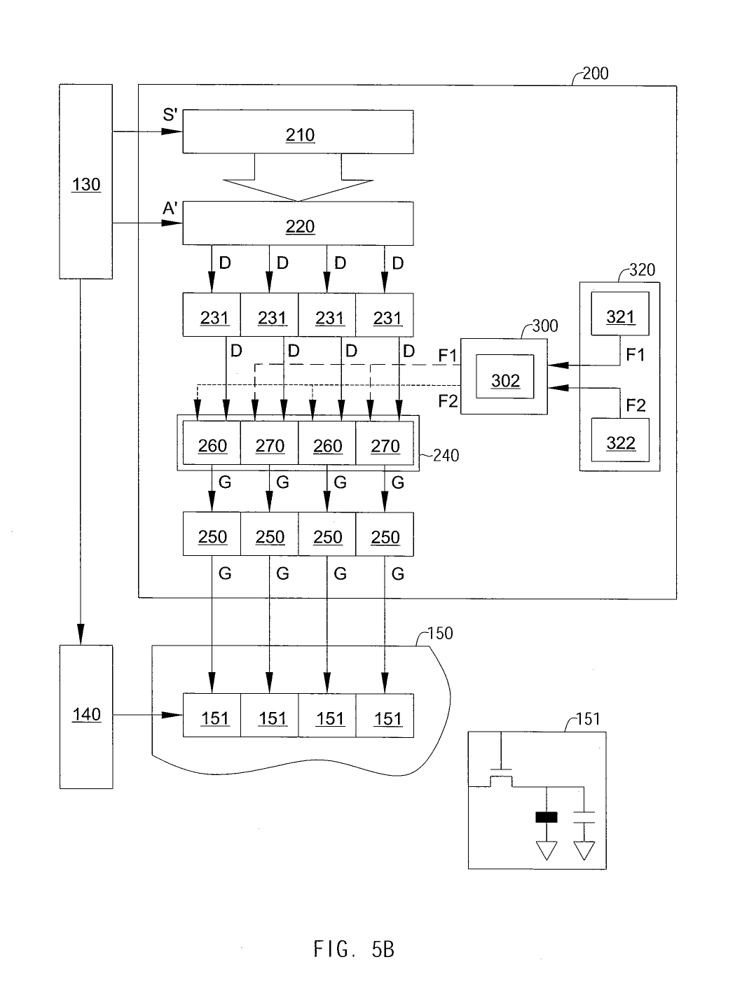

FIG. 5A and FIG. 5B illustrate another variation of the image driver 200 illustrated in FIG. 3. In the embodiment illustrated in FIG. 5A and FIG. 5B, the digital-to-analog conversion module 240 includes a plurality of first conversion units 260 and a plurality of second conversion units 270 connected to the multiplexer 300 to receive the adjustment signals F1, F2. In addition, the multiplexer 300 further includes a switching unit 302 for switching the adjustment signals F1, F2 based on the image to be displayed on the display panel 150. In the embodiment illustrated in FIG. 5A, the multiplexer 300 transmits the first adjustment signal F1 to the first conversion units 260 and transmits the second adjustment signal F2 to the second conversion units 252. However, in the embodiment illustrated in FIG. 5B, the switching unit 302 controls the multiplexer 300 to output the first adjustment signal F1 to the second conversion units 270 and the second adjustment signal F2 to the first conversion unit 260, based on the manufacture's configuration. In other words, the image driver 200 of the present embodiment can switch the adjustment signals F1/F2 transmitted to the first conversion units 260 and the second conversion units 270.

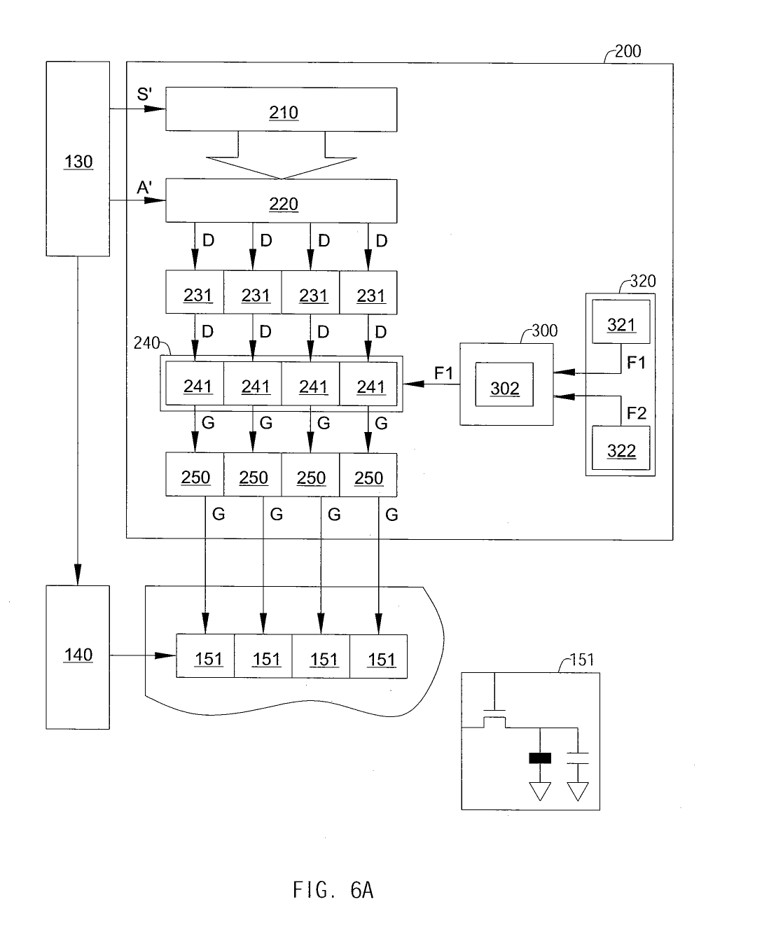

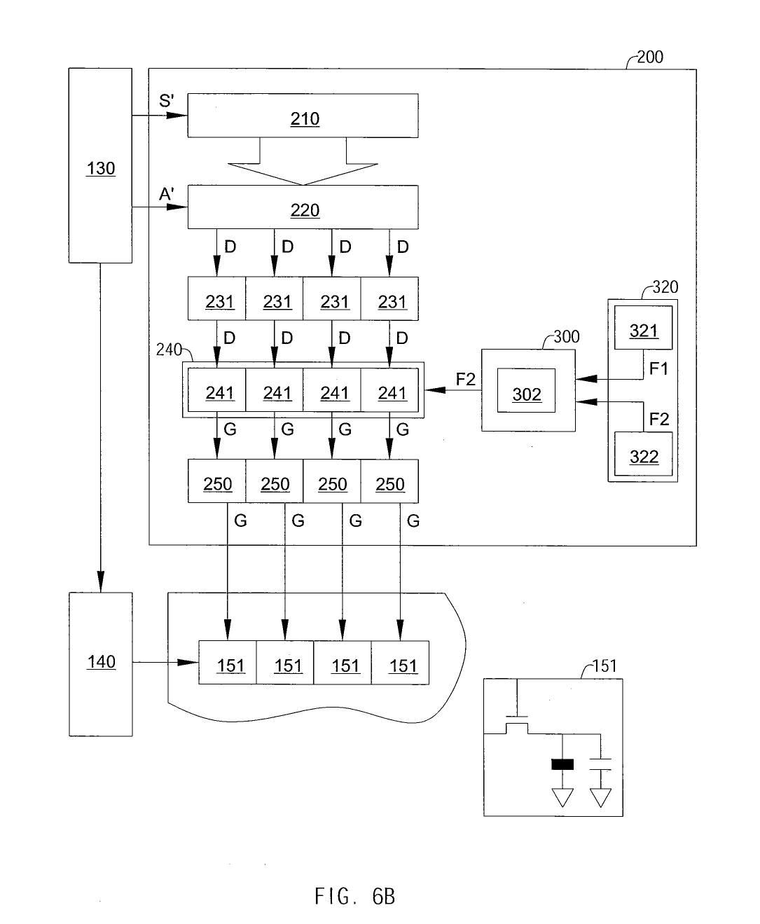

FIG. 6A and FIG. 6B illustrate a variation of the image driver 200 illustrated in FIG. 5A and FIG. 5B. In the embodiment illustrated in FIG. 6A, the multiplexer 300 outputs the first adjustment signals F1 to the digital-to-analog conversion module 240. However, in the embodiment illustrated in FIG. 6B, the switching unit 302 of the multiplexer 300 can control the multiplexer 300 to output the second adjustment signals F2 to the digital-to-analog conversion module 240 based on the configuration. When the image driver 200 of the present invention is installed in different types of displays with different display needs, the user can set the configuration using software or other means in order to use the image driver 200 to optimize the images displayed.

Furthermore, the image driver 200 of the present invention is preferably used to drive the liquid crystal molecules in the pixel units 151 of the display panel 150, but is not limited thereto. In different embodiments, the image driver 200 of the present invention can be used in the organic light emitting diode displays or other types of displays in order to correct the luminance variation of the display 150 with respect to the human visual system.

The above is a detailed description of the particular embodiment of the invention which is not intended to limit the invention to the embodiment described. It is recognized that modifications within the scope of the invention will occur to a person skilled in the art. Such modifications and equivalents of the invention are intended for inclusion within the scope of this invention.

What is claimed is:

1. An image driver, comprising:
an adjustment signal module for generating a plurality of adjustment signals, wherein the adjustment signals include a first adjustment signal and a second adjustment signal;
a multiplexer, connected to the adjustment signal module, selectively outputting one of the adjustment signals; and
a conversion module receiving the adjustment signal outputted from the multiplexer and outputting a driving signal based on the adjustment signal received.

2. The image driver of claim 1, wherein the multiplexer includes a plurality of multiplexer units, the conversion module includes a plurality of conversion units, each of the multiplexer units corresponds to one of the conversion units and receives the adjustment signal outputted from the adjustment signal module, the multiplexer unit transmits one of the adjustment signals to the corresponding conversion unit based on a selection signal, and the conversion unit generates the driving signal based on the adjustment signal received.

3. The image driver of claim 2 further including a selection signal module for transmitting at least one of a first selection signal and a second selection signal to the multiplexer units, wherein each multiplexer unit outputs the first adjustment signal when receiving the first selection signal and outputs the second adjustment signal when receiving the second selection signal.

4. The image driver of claim 1, wherein the conversion module includes a plurality of first conversion units and a plurality of second conversion units connected to the multiplexer, the multiplexer transmits the adjustment signal selected based on a selection signal to the first conversion units and the second conversion units.

5. The image driver of claim 4, wherein the multiplexer includes a switching unit for selectively transmitting the first adjustment signal and the second adjustment signal to the first conversion units and the second conversion units respectively or selectively transmitting the second adjustment signal and the first adjustment signal to the first conversion units and the second conversion units respectively.

6. A display, comprising:
an image driver, comprising:
an adjustment signal module for generating a plurality of adjustment signals, wherein the adjustment signals include a first adjustment signal and a second adjustment signal;
a multiplexer, connected to the adjustment signal module, selectively outputting one of the adjustment signals; and
a conversion module receiving the adjustment signal outputted from the multiplexer and outputting a driving signal based on the adjustment signal received; and
at least one pixel unit, connected to the image driver, receiving the driving signal.

7. The display of claim 6, wherein the multiplexer includes a plurality of multiplexer units, the conversion module includes a plurality of conversion units, each of the multiplexer units corresponds to one of the conversion units and receives the adjustment signal outputted from the adjustment signal module, the multiplexer unit transmits one of the adjustment signals to the corresponding conversion unit based on a selection signal, and the conversion unit generates the driving signal based on the adjustment signal received.

8. The display of claim 7 further including a selection signal module for transmitting at least one of a first selection signal and a second selection signal to the multiplexer units, wherein each multiplexer unit outputs the first adjustment signal when receiving the first selection signal and outputs the second adjustment signal when receiving the second selection signal.

9. The display of claim 6, wherein the conversion module includes a plurality of first conversion units and a plurality of second conversion units connected to the multiplexer, the multiplexer transmits the adjustment signal selected based on a selection signal to the first conversion units and the second conversion units.

10. The display of claim 9, wherein the multiplexer includes a switching unit for selectively transmitting the first adjustment signal and the second adjustment signal to the first conversion units and the second conversion units respectively or selectively transmitting the second adjustment signal and the first adjustment signal to the first conversion units and the second conversion units respectively.
